(19) United States
(12) Patent Application Publication
(10) Pub. No.: US 2007/0221999 A1
(43) Pub. Date: Sep. 27, 2007

(54) Semiconductor devices and methods of manufacture thereof

(75) Inventors: Chen-Bau Wu, Zhubei City (TW); Jiann-Tyng Tzeng, Hsin-Chu (TW); Chien-Shao Tang, Hsinchu City (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/387,613

(22) Filed: Mar. 23, 2006

(51) Int. Cl. H01L 29/76

(52) U.S. Cl. 257/384; 257/E29.156

(57) ABSTRACT

A semiconductor device includes a gate electrode, and a source region and a drain region proximate the gate electrode. A silicide region is disposed over a top surface of the gate electrode, the source region, or the drain region. A non-silicide region is disposed proximate the silicide region over an edge region of the top surface of the gate electrode, the source region, or the drain region.

### TECHNICAL FIELD

The present invention relates generally to the fabrication of semiconductor devices, and more particularly to the formation of silicide.

### BACKGROUND

Semiconductor devices are used in many electronic applications. Semiconductor devices may comprise analog or digital circuits, memory devices, logic circuits, peripheral support devices, or combinations thereof, formed on an integrated circuit (IC) die, as examples. Semiconductor devices are typically fabricated by sequentially depositing insulating (or dielectric) layers, conductive layers and semiconductive layers of material over a semiconductor substrate, and patterning the various layers using lithography to form circuit components and elements thereon.

A transistor is an element that is utilized extensively in semiconductor devices. There may be millions of transistors on a single integrated circuit (IC), for example. A common type of transistor used in semiconductor device fabrication is a metal oxide semiconductor field effect transistor (MOSFET), as an example. Transistors of semiconductor devices are typically formed by depositing a gate dielectric material over a substrate, and depositing a gate material over the gate dielectric material. The gate material and the gate dielectric material are patterned using lithography techniques, and dopants are implanted into the substrate proximate the gate and gate dielectric to form source and drain regions of the transistors.

The gate material of a transistor device often comprises a semiconductive material such as polysilicon. In some transistor designs, the gate material is silicided to increase the conductivity of the gate and improve the performance of the transistor. However, silicide processes may result in the formation of silicide in undesired regions of the transistor, which can have undesirable effects such as shorts, increased leakage currents, decreased yields, and/or degraded device performance, as examples.

What are needed in the art are improved methods of forming silicide on transistors and structures thereof.

### SUMMARY OF THE INVENTION

These and other problems are generally solved or circumvented, and technical advantages are generally achieved, by preferred embodiments of the present invention, which provide novel methods of forming silicide on transistor devices. The silicide is not formed on edge portions of gate electrodes and/or source and drain regions, which results in decreased leakage current.

In accordance with a preferred embodiment of the present invention, a semiconductor device includes a gate electrode, and a source region and a drain region proximate the gate electrode. A silicide region is disposed over the gate electrode, the source region, or the drain region. A non-silicide region is disposed proximate the silicide region over an edge region of a top surface of the gate electrode, the source region, or the drain region.

In accordance with another preferred embodiment of the present invention, a semiconductor device includes a gate electrode, the gate electrode including sidewalls and a first top surface, and a source region and a drain region proximate the gate electrode. The source region includes a second top surface and the drain region includes a third top surface. A first dielectric material is disposed on at least the sidewalls of the gate electrode. A second dielectric material is disposed over the first dielectric material, wherein the second dielectric material extends an electron conduction path from the first top surface of the gate electrode to the second top surface of the source region or to the third top surface of the drain region.

In accordance with yet another preferred embodiment of the present invention, a method of fabricating a semiconductor device includes providing a workpiece, forming a gate dielectric material over the workpiece, and forming a gate electrode material over the gate dielectric material. The method includes patterning the gate electrode material and the gate dielectric material, forming a gate electrode and a gate dielectric of a transistor, the gate electrode and the gate dielectric comprising sidewalls. A first dielectric material is formed over the sidewalls of at least the gate electrode, and a source region and a drain region are formed in the workpiece proximate the gate electrode and the gate dielectric. A second dielectric material is formed over the first dielectric material and over an edge region of a top surface of the gate electrode, the source region, or the drain region.

Advantages of preferred embodiments of the present invention include providing novel methods of forming silicide over portions of gate electrodes, source regions, or drain regions of a transistor. An insulating material is disposed over edge regions of the gate electrodes, source regions, or drain regions, so that silicide is not formed on the gate electrodes, source regions, or drain regions where the insulating material resides. Gate to source leakage current is reduced by embodiments of the present invention, by the insulating material disposed over the edges of the gate electrode, source region, or drain region, which extends an electron conduction path from a top surface of the gate electrode to the top surface of the source region or the drain region.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional view of a prior art transistor with a silicided gate electrode, source region, and drain region;

FIG. 2 shows a more detailed view of a portion of FIG. 1 proximate the gate and source region, illustrating the high leakage current that can occur in prior art transistors due to silicide encroachment on the sidewall spacers;

FIG. 3 is a graph of the gate current and gate to source leakage current of the transistor shown in FIGS. 1 and 2;

FIGS. 4 though 11 show cross-sectional views of an embodiment of the present invention, wherein an insulating material is formed over the sidewall insulator and edge regions of the gate electrode, source region, and/or drain region of a transistor; and

FIG. 12 shows an optional embodiment of the present invention, wherein after forming silicide over the gate electrode, source region, and/or drain region of a transistor, the insulating material is removed.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

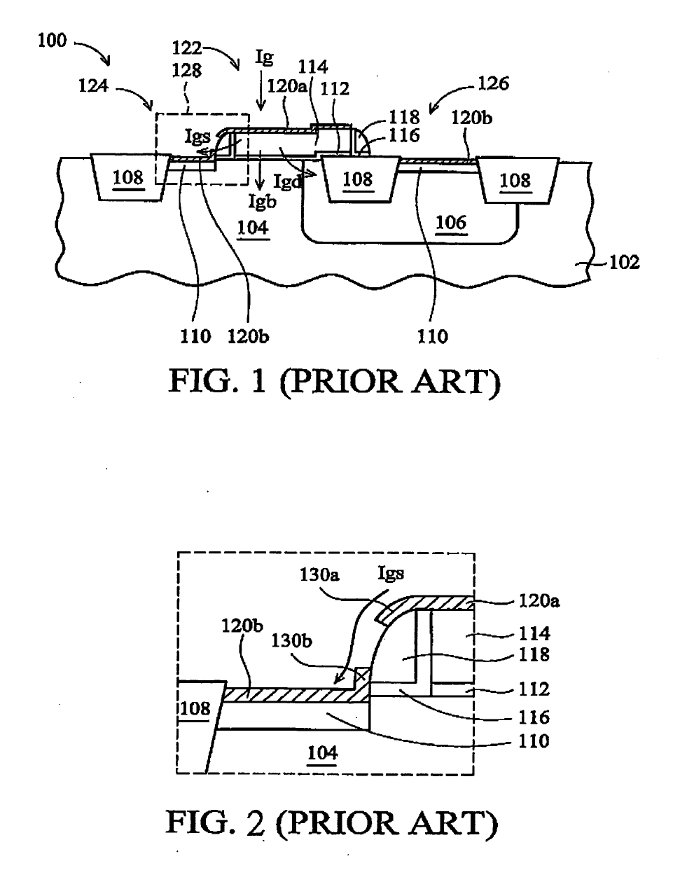

A prior art semiconductor device 100 is shown in FIG. 1. The semiconductor device 100 comprises a high voltage transistor 122 including a workpiece 102 with a high voltage p well 104 and a high voltage n well 106 formed therein. Shallow trench isolation (STI) regions 108 are formed between active areas of the workpiece 102. N+ regions 110 are formed in a top surface of the workpiece 102 within the high voltage p well 104 and high voltage n well 106, e.g., in the source region 124 and the drain region 126, respectively, as shown.

A gate dielectric 112 is disposed over the workpiece 102, and a gate electrode 114 comprising polysilicon is disposed over the gate dielectric 112. Sidewall spacers 116/118 comprising a liner 116 and a nitride material 118 are formed over the sidewalls of the gate electrode 114 and the gate dielectric 112, as shown. A silicide 120a is formed over the top surface of the gate electrode 112, and a silicide 120b is formed over top surfaces of the source region 124 and the drain region 126.

The gate current I_{g} of the transistor 122 comprises three components: the gate to source current I_{gs}, the gate to bulk current I_{gb}, and the gate to drain current I_{gd}. The gate current I_{g} is calculatable using Equation 1:
I_{g}=I_{gs}+I_{gb}+I_{gd} Equation 1:

Ideally, if the transistor 122 is off, then the gate current I_{g} would be zero. However, in a normal condition, the gate current I_{g} of a transistor 122 shown in FIGS. 1 and 2 is typically less than about 1×10⁻¹² Amperes. In an abnormal condition, e.g., in a transistor 122 having excessive leakage current, the gate current I_{g} may be greater than about 1×10⁻⁹ Amperes, for example. Preferably, the gate current I_{g} of a transistor 122 is maintained within a normal limit, e.g., at less than about 1×10⁻¹² when the transistor 122 is in the “on” or “off” state.

A problem with the prior art semiconductor device 100 shown in FIG. 1 is that the silicide 120a and silicide 120b tends to encroach over the sidewall spacers 116 and 118, as shown in FIG. 2, which shows a more detailed view of a portion 128 of the transistor 122 shown in FIG. 1 proximate the electrode 114 and source region 124. The silicide encroachment, e.g., at regions 130a and 130b where the silicide is formed over portions of the sidewall spacers 116/118, is caused by silicon diffusion upwardly from the N+ regions 110 within the workpiece 102 along the sidewall spacers 116/118 in the source region 124 or the drain region 126, and downwardly along the sidewall spacers 116/118 from the polysilicon material of the gate electrode 114, respectively. The silicide encroachment 130a and 130b occurs during the formation of the silicide regions 120a and 120b, for example. The silicide encroachment 130a and 130b creates an electrical path for increased gate to source current I_{gs} to flow across; e.g., causing an increase in the gate to source I_{gs} leakage current. The silicide encroachment 130a and 130b also degrades the gate to source isolation compatibility, which is particularly a problem for high voltage transistor devices, for example.

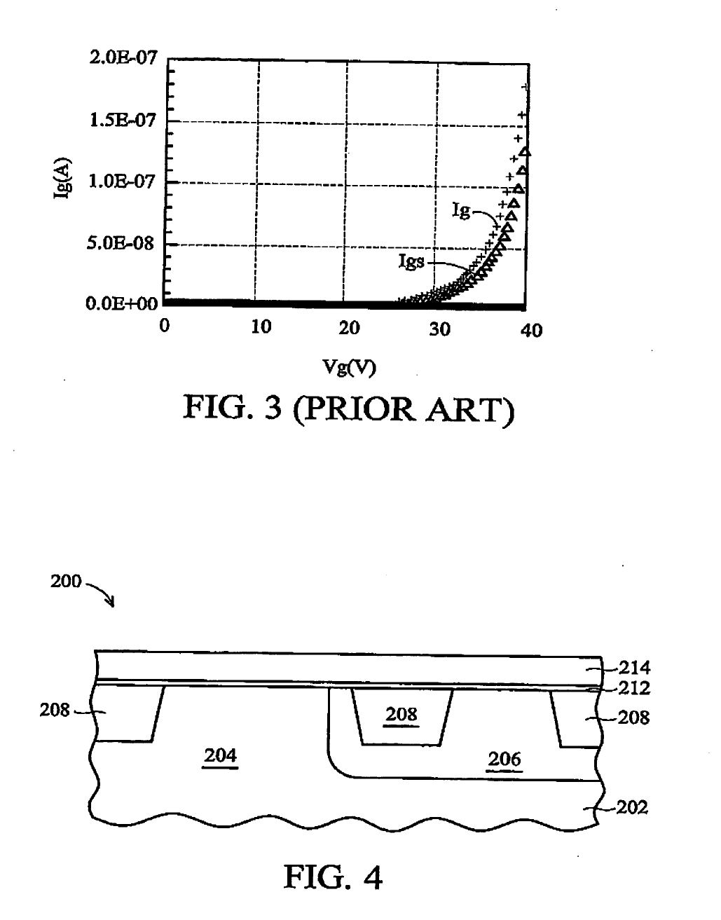

FIG. 3 is a graph of the gate current I_{g} and gate to source leakage current I_{gs} of the transistor shown in FIGS. 1 and 2, wherein the transistor comprises a 0.18 μm 1.8 volt (V) device, e.g., wherein the gate electrode 114 comprises a width of about 0.18 μm, and the gate to source voltage (V_{gs}) and drain to source voltage (V_{ds}) comprises about 1.8 V. The graph illustrates that the gate to source leakage current I_{gs} contributes to the majority of the gate current I_{g}.

Thus, what are needed in the art are improved methods of forming silicide over gate electrodes, source regions, and drain regions of transistors and structures thereof, in which silicide encroachment onto the sidewall spacers is reduced or eliminated.

Embodiments of the present invention achieve technical advantages by providing novel methods of forming silicide and transistor structures, wherein the gate to source leakage current I_{gs} is reduced. An insulating material is formed on the edge regions of the top surface of the gate electrodes, source regions, and drain regions of transistors, so that when silicide is formed on these areas, the silicide is not formed on the edge regions, thus eliminating silicide encroachment and reducing the gate to source leakage current I_{gs}.

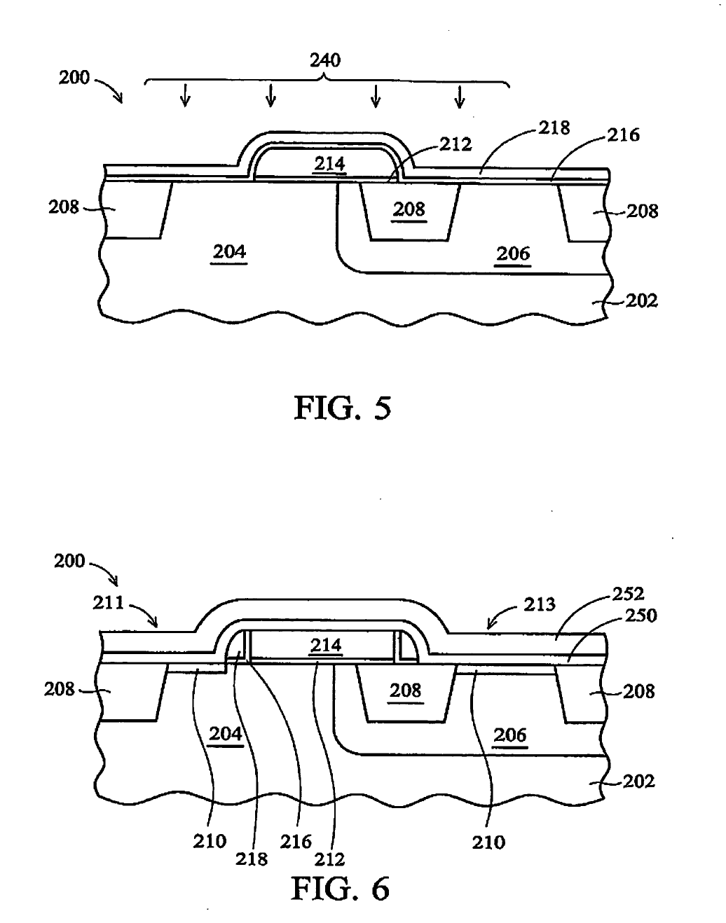

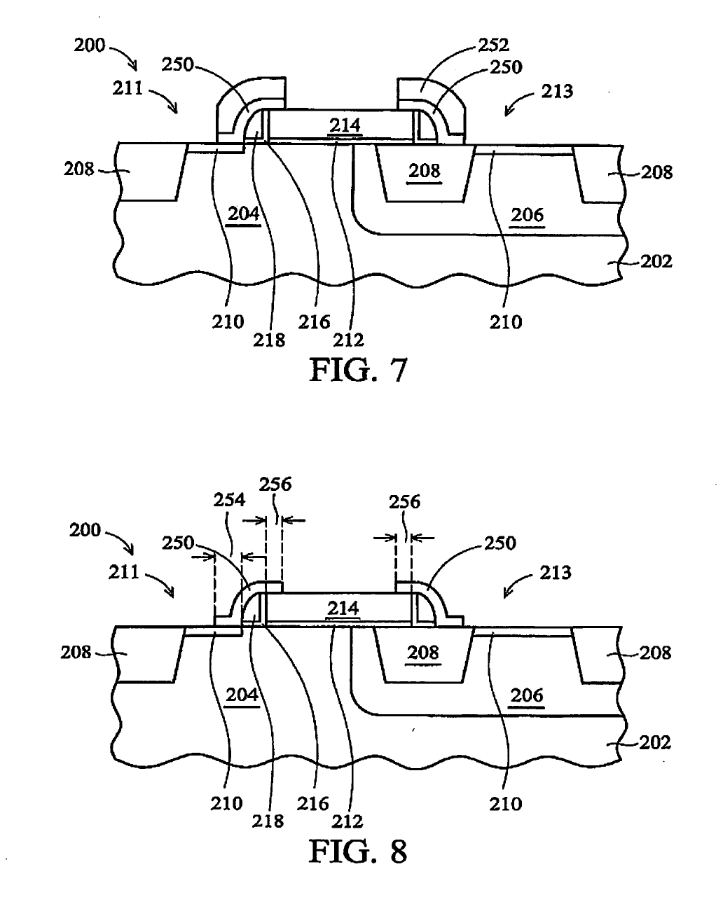

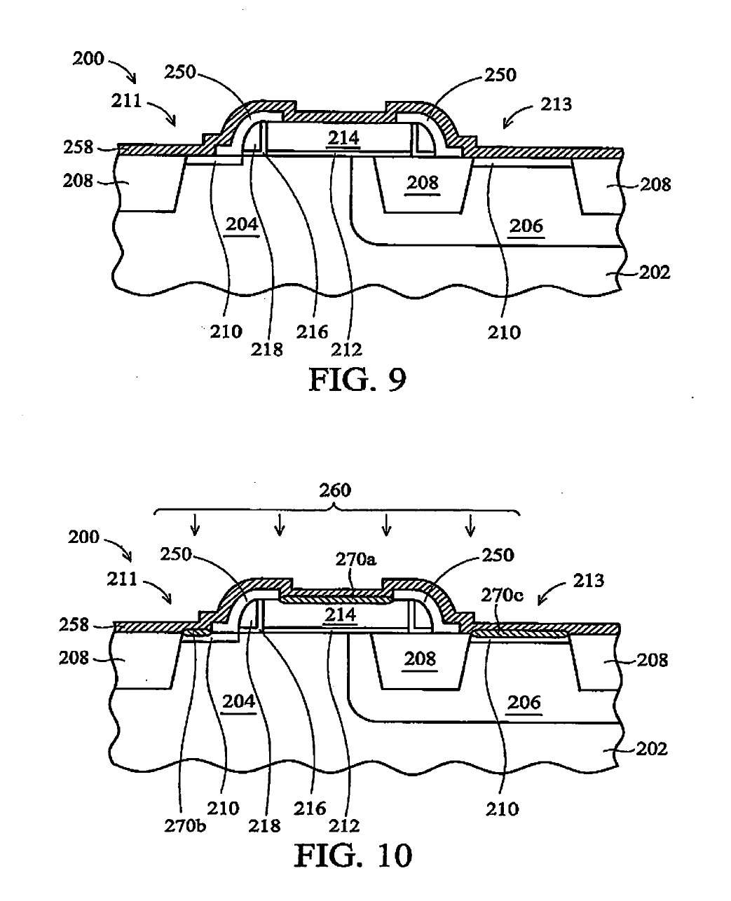

FIGS. 4 though 11 show cross-sectional views of an embodiment of the present invention, wherein an insulating material is formed over the sidewall insulator and edge regions of the top surfaces of the gate electrode, source region, and/or drain region of a transistor. A preferred method of manufacturing a semiconductor device 200 in accordance with an embodiment of the present invention will next be described. Only one transistor is shown in each of the figures; however, preferably a plurality of transistors are manufactured simultaneously in accordance with preferred embodiments of the present invention, for example.

Referring next to FIG. 4, first, a workpiece 202 is provided. The workpiece 202 may include a semiconductor substrate comprising silicon or other semiconductor materials covered by an insulating layer, for example. The workpiece 202 may also include other active components or circuits, not shown. The workpiece 202 may comprise silicon oxide over single-crystal silicon, for example. The workpiece 202 may include other conductive layers or other semiconductor elements, e.g., transistors, diodes, etc. Compound semiconductors, GaAs, InP, Si/Ge, or SiC, as examples, may be used in place of silicon. The workpiece 202 may comprise a silicon-on-insulator (SOI) substrate, for example. In the embodiment shown in FIGS. 3 through 11, the workpiece 202 preferably comprises a p-substrate, for example, although alternatively, the workpiece 202 may comprise an n type substrate.

Next, high voltage p wells 204 and high voltage n wells 206 are formed in the workpiece 202, e.g., using implantation processes and anneal processes. For example, one portion of the workpiece 202 may be masked with a photoresist or hard mask (not shown) while the other portion of the workpiece 202 is implanted with a p type or n type dopant. STI regions 208 are then formed within the workpiece 202, e.g., by forming trenches using lithography, filling the trenches with an insulating material, such as silicon dioxide or silicon nitride, or combinations or multiple layers thereof, and removing excess insulating material from over the top surface of the workpiece 202 using a chemical mechanical polishing (CMP) process, etch process, or combinations thereof, as examples.

Next, optionally, low voltage n wells and low voltage p wells (not shown) may be formed in the workpiece 202. For example, if the semiconductor device 200 comprises an integrated circuit that includes both high voltage devices and low voltage devices formed in a single chip or integrated circuit, the low voltage n wells and p wells are preferably formed next. Low voltage n wells and low voltage p wells may be used in transistors with a relatively low operating voltage, such as about 15 V or less, but higher voltage transistors may not require low voltage n and p wells, such as transistor devices that operate at about 20 V or higher, as examples.

A gate dielectric material 212 is formed over the workpiece 202, e.g., over the top surface of the STI regions 208, and over the top surface of the high voltage p well 204 and the high voltage n well 206 formed in the workpiece 202, as shown in FIG. 4. The gate dielectric material 212 preferably comprises an insulating material or dielectric material such as silicon dioxide, other insulators, or combinations or multiple layers thereof, as examples, although alternatively, the gate dielectric material 212 may comprise other materials. The gate dielectric material 212 preferably comprises a thickness of about 2,000 Angstroms or less, as an example, although alternatively, the gate dielectric material 212 may comprise other dimensions. The gate dielectric material 212 preferably comprises a thickness of about 250 to 1,500 Angstroms, in one embodiment, for example, if the transistor to be manufactured comprises a high voltage device. The gate dielectric material 212 may be formed by a thermal oxidation process, chemical vapor deposition (CVD), or physical vapor deposition (PVD), as examples, although alternatively, other deposition methods may also be used.

A gate electrode material 214 is formed over the gate dielectric material 212, as shown in FIG. 4. The gate electrode material 214 preferably comprises a semiconductive material, such as polycrystalline silicon (polysilicon), and alternatively may comprise amorphous silicon, other semiconductive materials, or combinations or multiple layers thereof, as examples, although alternatively, the gate electrode material 214 may comprise other materials. The gate electrode material 214 preferably comprises a thickness of about 5,000 Angstroms or less, as an example, although alternatively, the gate electrode material 214 may comprise other dimensions. The gate electrode material 214 preferably comprises a thickness of about 1,500 to 4,000 Angstroms, in one embodiment, for example, if the transistor to be manufactured comprises a high voltage device. The gate electrode material 214 may be formed by CVD or PVD, as examples, although alternatively, other deposition methods may also be used.

The gate electrode material 214 and the gate dielectric material 212 are patterned using lithography to form a gate electrode 214 and a gate dielectric 212 of a transistor, as shown in FIG. 5. For example, a layer of photoresist and/or an optional hard mask (not shown) may be deposited over the top surface of the gate electrode material 214, and the layer of photoresist may be exposed to energy using a lithography mask to transfer the pattern on the lithography mask to the layer of photoresist. The layer of photoresist is then used as a mask to pattern the gate electrode material 214 and the gate dielectric material 212, or alternatively, the layer of photoresist is used as a mask to pattern the hard mask, and then the layer of photoresist and/or the hard mask is used as a mask to pattern the gate electrode material 214 and the gate dielectric material 212, for example. The layer of photoresist and the hard mask are then removed.

Exposed portions of the workpiece 202 may then optionally be implanted with dopants to form lightly doped regions. For example, a portion of the workpiece 202 may be masked while n dopants are implanted in some regions to form n doped lightly doped diffusion (NLDD) regions in the workpiece 202, and another portion of the workpiece 202 may be masked while p type dopants are implanted in other regions to form p doped lightly doped diffusion (PLDD) regions in the workpiece 202, not shown.

Sidewall spacers 216/218 are formed over the sidewalls of the gate electrode 214 and the gate dielectric 212, as shown in FIGS. 4 and 5. To form the sidewall spacers 216/218, an optional liner 216 is formed over the top surface of the workpiece 202, over the sidewalls of the gate dielectric 212 and the gate electrode 214, and over the top surface of the gate electrode 214, as shown in FIG. 5. The liner 216 preferably comprises an insulating material or dielectric material, such as silicon dioxide, in one embodiment, although alternatively, the liner 216 may comprise silicon nitride or other insulating materials. The liner 216 is preferably substantially conformal and preferably comprises a thickness of about 1,500 Angstroms or less, for example, although alternatively, the liner 216 may comprise other dimensions.

An insulating material 218 is formed over the optional liner 216, or over the sidewalls and top surface of the gate electrode 214, sidewalls of the gate dielectric 212, and exposed top surface of the workpiece 202, if the liner 216 is not included. The insulating material 218 preferably comprises a dielectric material, such as silicon nitride in one embodiment, although alternatively, the insulating material 218 may comprise silicon dioxide, other insulating materials, or combinations thereof, as examples. The insulating material 218 is preferably substantially conformal as deposited, and preferably comprises a thickness of about 2,000 Angstroms or less, for example, although alternatively, the insulating material 218 may comprise other dimensions.

The insulating material 218 and the optional liner 216 are etched to remove the insulating material 218 and the liner 216 from the top surface of the gate electrode 214 and the top surface of the workpiece 202, yet leaving a portion of the insulating material 218 and the optional liner 216 left residing on the sidewalls of the gate dielectric 212 and the gate electrode 214, as shown in FIG. 6. For example, a directional etch process 240 such as an anisotropic etch process may be used to etch the insulating material 218 and the liner 216. After the etch process 240, the total width of the sidewall spacers 216/218 preferably comprises about 1,500 to 3,000 Angstroms, although alternatively, the total width of the sidewall spacers 216/218 may alternatively comprise about 3,500 Angstroms or less, for example.

After forming the sidewall spacers 216/218, exposed portions of the workpiece 202 may be implanted with dopants to form N+ regions 210 in the top surface of the workpiece 202, as shown in FIG. 6. The source region 211 includes the N+ region 110, the optional lightly doped region of the workpiece 202 (not shown), the optional low voltage n well (also not shown) of the workpiece 202, and the high voltage p well 204. The drain region 213 includes the N+ region 110, the optional lightly doped region of the workpiece 202 (not shown), the optional low voltage p well (also not shown) of the workpiece 202, and the high voltage n well 206.

Next, an insulating material 250 is formed over the exposed top surface of the workpiece 202, over the top surface of the gate electrode 214, and over the sidewall spacers 216/218, as shown in FIG. 6. The insulating material 250 is preferably substantially conformal, as shown. The insulating material 250 preferably comprises a dielectric material such as silicon dioxide, although alternatively, other insulating materials may be used. The insulating material 250 may comprise silicon dioxide, silicon nitride, other insulators, or combinations or multiple layers thereof, as examples. The insulating material 250 preferably comprises a thickness of about 1,500 Angstroms or less, and more preferably comprises a thickness of about 200 to 1,000 Angstroms in some embodiments, for example.

A layer of photoresist 252 is deposited over the insulating material 250, as shown in FIG. 6. The layer of photoresist 252 preferably comprises a thickness of about 1 μm or less, as an example. The layer of photoresist 252 is patterned using lithography with a desired pattern for the insulating material 250 that will be used to protect portions of the top surface of the gate electrode 214 and the workpiece 202 in the source and drain regions 211 and 213 during a subsequent silicide process, to be described further herein.

The layer of photoresist 252 is used as a mask while portions of the insulating material 250 are removed in an etch process, leaving the structure shown in FIG. 7. The layer of photoresist 252 is then removed, leaving the structure shown in FIG. 8.

Preferably, the remaining insulating material 250 completely covers the sidewall spacers 216/218, as shown in FIG. 8. The insulating material 250 also preferably extends over an edge region of the top surfaces of the source region and/or drain region by an amount comprising a dimension represented by region 254. The edge region 254 of the source region (and also of the drain region, not shown) preferably comprises an edge of the source region 211 and/or drain region 213 proximate the gate electrode, as shown. The insulating material 250 preferably extends over an edge region of the top surface of the gate electrode 214 by an amount comprising a dimension represented by 256. Preferably the edge region 256 of the gate electrode 214 includes an edge proximate the source region 211 and also includes an edge proximate the drain region 213, as shown. The edge region 256 may also include a first edge proximate the reader as the page of FIG. 8 is viewed, and also may include a second edge farthest from the reader as the page of FIG. 8 is viewed, for example, not shown. The gate electrode 214 may comprise a square or rectangular shape, for example, and the edge region 256 may be disposed on all four sides of the gate electrode 214, although alternatively, the gate electrode 214 may comprise other shapes and may comprise an edge region 256 that is fully or partially covered by the insulating material 250, for example, not shown. The dimensions of edge regions 254 and 256 preferably comprise about 0.5 μm or less, for example.

Preferably, the insulating material 250 is left disposed completely over the sidewall spacer 216/218 proximate the gate electrode 214, as shown, in some embodiments. In some embodiments, the insulating material 250 is preferably left disposed over a top portion of the gate electrode 214, e.g., in an edge region 256. In other embodiments, the insulating material 250 is preferably left disposed over a top portion of the source region 211 or the drain region 213 of the transistor, e.g., as shown in edge region 254. In yet other embodiments, the insulating material 250 is preferably left disposed over a top portion of the gate electrode 214, e.g., in an edge region 256, and is preferably left disposed over a top portion of the source region 211 or the drain region 213 of the transistor, e.g., in an edge region 254.

Exposed portions of the workpiece 202 and the gate electrode 214 are silicided, forming silicided regions 270a, 270b, and 270c on the top surface of the gate electrode 214 and on the top surface of the workpiece 202 in the source region 211 and the drain region 213, respectively, as shown in FIG. 10.

For example, to form the silicided regions 270a, 270b, and 270c, a conductive material 258 may be deposited over exposed portions of the top surface of the workpiece 202, over the insulating material 250, and over exposed portions of the gate electrode 214, as shown in FIG. 9. The conductive material 258 preferably comprises Ti, Co, Ni, or combinations thereof, as examples, although alternatively, other metals may be used. The conductive material 258 preferably comprises a thickness of about 500 Angstroms or less, as an example, although other dimensions may be used. The workpiece 202 is then heated using an anneal process 260, as shown in FIG. 10. The anneal process 260 preferably comprises a temperature of about 600 degrees C. to about 900 degrees C. and may comprise a duration of about 30 seconds, as examples, although alternatively, the anneal process 260 may comprise other processing parameters, for example.

The anneal process 260 causes a first portion of the conductive material 258, e.g., a portion proximate the gate electrode 214 and workpiece 202, to combine with the semiconductive material of the gate 214 and the workpiece 202, forming the silicide regions 270a, 270b, and 270c. The silicide regions 270a, 270b, and 270c preferably comprise the semiconductive material of the workpiece 202 and the gate electrode 214 combined with Ti, Co, Ni, or combinations thereof, as examples, although the silicide regions 270a, 270b, and 270c may alternatively comprise other materials. For example, if the workpiece 202 comprises silicon and the gate electrode 214 comprises silicon, the silicide regions 270a, 270b, and 270c preferably Ti, Co, Ni, or combinations thereof with silicon. The silicide regions 270a, 270b, and 270c preferably comprise a thickness of about 300 Angstroms, as an example, although alternatively, the silicide regions 270a, 270b, and 270c may comprise other dimensions.

The conductive material 258 is then removed, as shown in FIG. 11. The remaining structure includes a transistor 282 including a gate electrode 214 having a partially silicided top surface. For example, silicide region 270a is disposed over a central region of the gate electrode 214, and a non-silicided region is disposed proximate the edge region 256 of the gate electrode 214, e.g., due to the presence of the insulating material 250 in the edge region 256, which prevents the silicidation of the top surface of the gate electrode 214 in the edge region 256.

Likewise, the source and/or drain regions 211 and 213 are at least partially silicided, e.g., as shown in the left side of the figure at silicide region 270b in the source region 211. In FIG. 1, the silicide region 270b is formed over a source region 211 of a transistor device 282, for example. A portion of the top surface of the workpiece 202 in the source region 211 in the edge region 254 comprises a non-silicided region, due to the presence of the insulating material 250 in the edge region 254 during the silicidation process, which prevents the silicidation of the top surface of the workpiece 202 in the edge region 254.

In the drawing shown in FIG. 11, the drain region 213 of the transistor 282 is completely silicided, as shown on the right side of the figure in silicide region 270c. Alternatively, the drain region 213 may also be partially silicided as shown at silicide region 270b of the source region 211, in accordance with embodiments of the present invention. For example, STI region 208 disposed beneath the right side of the gate electrode 214 may not be included, and the gate dielectric 214 and the gate electrode 214 in the drain region 213 may be formed directly over the well 206, as is shown on the left side of the figure in the source region 211, in some embodiments.

The silicide regions 270a, 270b, and 270c increase the conductivity in the regions they are formed over, e.g., of the gate electrode 214 and the source and drain regions 211 and 213 formed in the workpiece 202. The insulating material 250 left residing over the sidewall spacer 216/218, an edge region 256 of the gate electrode 214, and an edge region 254 of the source region and/or drain region 211 and 213, preferably extends or increases an electron conduction path 280 from a top portion of the gate electrode 214 to the source region 211 and/or the drain region 213, in accordance with embodiment of the present invention, resulting in decreased leakage current (e.g., decreased gate to source current or gate to drain current).

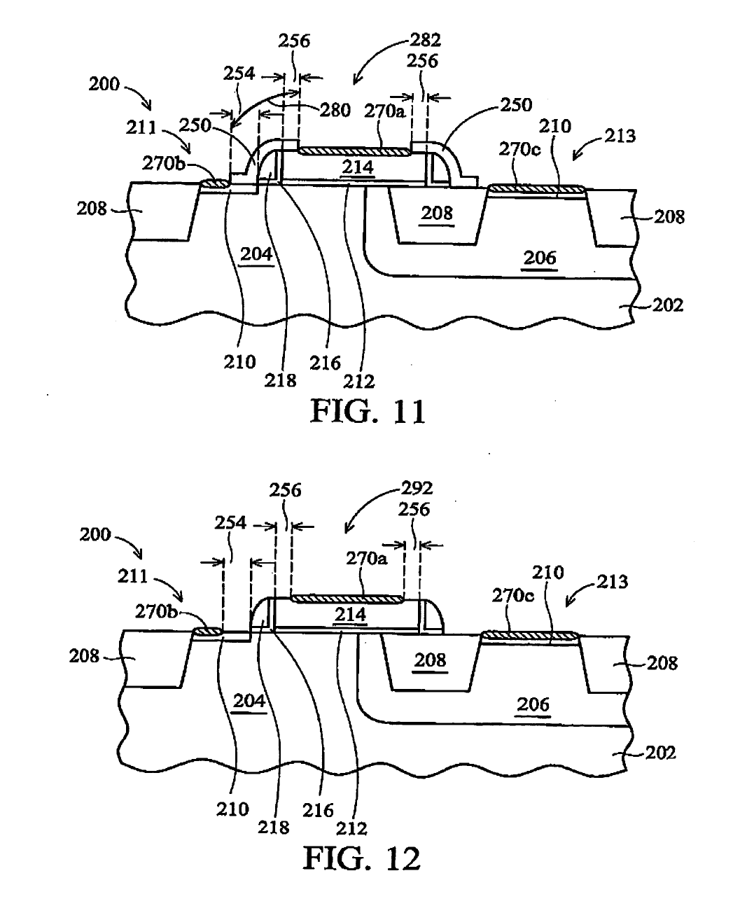

FIG. 12 shows an optional embodiment of the present invention, wherein after forming silicide 270a, 270b, and 270c over the gate electrode 214, source region 211, and/or drain region 213 of the transistor 292, the insulating material 250 (the insulating material 250 is not shown in FIG. 12: see FIG. 11) is removed. After forming the silicide regions 270a, 270b, and/or 270c, the insulating material 250 may be removed using an etch process, leaving the structure shown in FIG. 12. However, in some embodiments, preferably the insulating material 250 is left remaining in the structure, as shown in FIG. 11.

Advantages of preferred embodiments of the present invention include providing novel methods of forming silicide 270a, 270b, and 270c over portions of gate electrodes 214 or source and drain regions 211 and 213 of transistors 282 and 292. An insulating material 250 is disposed over edge regions 256 and 254 of the gate electrodes 214, source regions, 211 and/or drain regions 213, so that silicide 270a, 270b, and 270c is not formed on the edge regions 256 and 254 of the top surfaces of the gate electrodes 214, source regions 211, and/or drain regions 213 where the insulating material 250 resides. Gate to source leakage current I_{gs} is reduced by embodiments of the present invention, by the insulating material 250 disposed over the edges 256 and 254 of the gate electrode 214, source region 211, and/or drain region 213, which extends an electron conduction path 280 from a top surface of the gate electrode 214 to the source region 211 or the drain region 213. Transistors 282 and 292 with improved gate to source isolation capability are achieved by embodiments of the present invention.

Embodiments of the present invention are particularly advantageous when used in high voltage applications, e.g., when implemented in transistors having a threshold voltage (Vₜ) of about 0.8 to 2.5 volts, a gate to source voltage (V_{gs}) of about 30 volts or greater, and a drain to source voltage (V_{ds}) of about 30 volts or greater, as examples. In one embodiment, for example, a transistor may be formed having a gate to source voltage V_{gs} of about 40 V and a drain to source voltage V_{ds} of about 40 V, and having a very low gate to source leakage current, e.g., an I_{gs} of about 1×10⁻¹² Amperes or less at high V_{gs}, e.g., of about 40 V, for example, by preventing the formation of silicide at the edge regions 254 and 256 using the insulating material 250, as described herein. Transistors 282 and 292 having other voltages and currents may also be fabricated using the embodiments described herein. Embodiments of the present invention may be implemented in low or high voltage applications, or in semiconductor devices including both low and high voltage transistors 282 and 292 formed on the same chip, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device, comprising:
a gate electrode;
a source region and a drain region proximate the gate electrode;
a silicide region disposed over the gate electrode, the source region, or the drain region; and
a non-silicide region disposed proximate the silicide region over an edge region of a top surface of the gate electrode, the source region, or the drain region.

2. The semiconductor device according to claim 1, wherein the silicide region and the non-silicide region are disposed over the top surfaces of the gate electrode, the source region, and the drain region.

3. The semiconductor device according to claim 1, further comprising an insulating material disposed over the non-silicide region over the edge region of the top surface of the gate electrode, the source region, or the drain region.

4. The semiconductor device according to claim 3, wherein the insulating material comprises an oxide material comprising a thickness of about 1,500 Angstroms or less.

5. The semiconductor device according to claim 1, wherein the non-silicide region disposed over the edge region of the gate electrode, and the source region comprises a width of about 0.5 μm or less.

6. The semiconductor device according to claim 1, wherein the silicide region comprises Ti, Co, Ni, or combinations thereof combined with Si.

7. The semiconductor device according to claim 1, wherein the gate electrode, the source region, and the drain region comprise a transistor having a threshold voltage (Vₜ) of about 0.8 to 2.5 volts, a gate to source voltage (V_{gs}) of about 30 volts or greater, and a drain to source voltage (V_{ds}) of about 30 volts or greater.

8. A semiconductor device, comprising:
a gate electrode, the gate electrode comprising sidewalls and a first top surface;
a source region and a drain region proximate the gate electrode, the source region comprising a second top surface, the drain region comprising a third top surface;
a first dielectric material disposed on at least the sidewalls of the gate electrode;
a second dielectric material disposed over the first dielectric material, wherein the second dielectric material extends an electron conduction path from the first top surface of the gate electrode to the second top surface of the source region or to the third top surface of the drain region.

9. The semiconductor device according to claim 8, wherein the second dielectric material is disposed over an edge region of the first top surface of the gate electrode.

10. The semiconductor device according to claim 8, wherein the second dielectric material is disposed over an edge region of the second top surface of the source region or over an edge region of the third top surface of the drain region.

11. The semiconductor device according to claim 8, wherein the first dielectric material comprises a nitride material, and wherein the second dielectric material comprises an oxide material.

12. The semiconductor device according to claim 8, further comprising:
a silicide region disposed over a portion of the gate electrode, the source region, or the drain region; and
a non-silicide region disposed proximate the silicide region over an edge region of the first top surface of the gate electrode, the second top surface of the source region, or the third top surface of the drain region.

13-21. (canceled)

22. A semiconductor device, comprising:
a workpiece;
a gate electrode and a gate dielectric of a transistor, the gate electrode and the gate dielectric comprising sidewalls;
a first dielectric material over the sidewalls of at least the gate electrode;
a source region and a drain region in the workpiece proximate the gate electrode and the gate dielectric; and
a second dielectric material over the first dielectric material and over an edge region of a top surface of the gate electrode, the source region, or the drain region.

23. The semiconductor device according to claim 22, further comprising a silicide region over at least a portion of the top surface of the gate electrode, the source region, or the drain region.

24. The semiconductor device according to claim 23, wherein at least a portion of the top surface of the gate electrode, the source region, or the drain region comprises essentially no silicide on the edge portion of the top surface of the gate electrode, the source region, or the drain region where the second dielectric material resides.

25. The semiconductor device according to claim 23, wherein at least a portion of the top surface of the gate electrode, the source region, or the drain region comprises essentially no silicide on the edge portion of the top surface of the gate electrode, the source region, or the drain region.

26. The semiconductor device according to claim 23, wherein the gate electrode, the source region, or the drain region comprise a semiconductor material, and wherein the silicide comprises Ti, Co, Ni, or combinations thereof with Si.

27. The semiconductor device according to claim 23, wherein the semiconductor device further comprises:
a first region over the first dielectric material, on an edge portion of the gate electrode, on an edge portion of the source region, or on an edge portion of the drain region;
a second region over a central region of the gate electrode, over a portion of the source region, or over a portion of the drain region, wherein the first region has essentially no silicide and the second region is silicided.

28. The semiconductor device according to claim 27, wherein the first region over the first dielectric material comprises a second dielectric material of about 1,500 Angstroms or less of an oxide material.

29. The semiconductor device according to claim 22, wherein the semiconductor device further comprises:
a first insulating material over the sidewalls of the gate electrode, the sidewalls of the gate dielectric, and a portion of the top surface of the workpiece; and
a second insulating material over the first insulating material.

30. The semiconductor device according to claim 29, wherein the first insulating material comprises about 1,000 Angstroms or less of silicon dioxide, and wherein the second insulating material comprises about 1,500 Angstroms or less of silicon nitride.
